(19) United States
(12) Patent Application Publication
(10) Pub. No.: US 2011/0243280 A1
(43) Pub. Date: Oct. 6, 2011

(54) RECEIVER AND RECEIVING METHOD

(75) Inventor: Takaya HAYASHI, Osaka (JP)

(73) Assignee: Panasonic Corporation, Osaka (JP)

(21) Appl. No.: 13/160,671

(22) Filed: Jun. 15, 2011

Related U.S. Application Data
(63) Continuation of application No. PCT/JP2009/006894, filed on Dec. 15, 2009.

(30) Foreign Application Priority Data
Dec. 15, 2008 (JP) 2008-318599

(51) Int. Cl. H03D 1/00

(52) U.S. Cl. 375/340

(57) ABSTRACT

A receiver is provided which is capable of proper demodulation and error correction in various transmission environments. A receiver for receiving a digitally modulated signal includes a demodulator which selects one demodulation scheme from a plurality of predetermined demodulation schemes based on the received signal, and which demodulates the received signal using the selected demodulation scheme to generate a demodulated signal, and a demapper which obtains metric data by making a soft decision on the demodulated signal. The demapper converts the demodulated signal into the metric data according to the selected demodulation scheme.

### CROSS-REFERENCE TO RELATED APPLICATION

This is a continuation of PCT International Application PCT/JP2009/006894 filed on Dec. 15, 2009, which claims priority to Japanese Patent Application No. 2008-318599 filed on Dec. 15, 2008. The disclosures of these applications including the specifications, the drawings, and the claims are hereby incorporated by reference in its entirety.

### BACKGROUND

The present disclosure relates to receivers for receiving digitally modulated signals.

Digital terrestrial television broadcasting using the orthogonal frequency division multiplexing (OFDM) technique has started in Japan, Europe, etc., and in addition to receiving broadcasts by a receiver installed indoors, it is becoming more common to receive broadcasts on the move using a mobile terminal or a receiver installed in an automobile etc. In Japan, a service called one segment broadcasting is also becoming popular in which a part of the center portion of the frequency band of a digital terrestrial television broadcasting channel can be received by a mobile terminal etc.

The OFDM technique is a technique in which information such as video and/or audio is assigned to multiple carriers orthogonal to one another for transmission. In the OFDM technique, an inverse fast Fourier transform (IFFT) is performed on signals to be transmitted in the transmission side, and a fast Fourier transform (FFT) is performed in the reception side for demodulation of received signals.

In receiving a transmitted signal, the quality of the received signal may be degraded depending on the characteristics of the transmission channel through which the signal has passed. The degradation of signal quality is caused by various factors; in general, examples of degradation factors in receiving digital terrestrial broadcasting include multipath interference, additive white Gaussian noise (AWGN) interference, etc. Multipath interference induces amplitude and/or phase distortion of a received signal due to reflection of radio waves by buildings etc. Meanwhile, if a broadcast is received at a location far from the transmission site, the received power level is reduced, and thus thermal noise of the tuner is likely to have more significant effect, thereby causing AWGN interference to occur.

Patent Documents 1 and 2 listed below describe examples of a receiver for reducing the effect of interference by performing processes such as demodulation and error correction based on the conditions of the interference introduced, among different types of interference introduced depending on such characteristics of a transmission channel (hereinafter referred to as “channel response”). Typically, a receiver for receiving an OFDM signal estimates the channel response based on a pilot signal whose amplitude and phase are known, and corrects (equalizes) the amplitude and/or phase distortion of the received signal based on the estimated channel response. The receiver described in Patent Document 1 has a plurality of preset filter coefficients used for a filter to estimate the channel response, and determines the optimum filter coefficient by sequentially switching between the filter coefficients and detecting the quality of the demodulated signal for each of the filter coefficients.

The receiver described in Patent Document 2 is provided focusing on the fact that the transfer function of a transmission channel (i.e., channel response) changes when multipath interference occurs. That is, the receiver described in Patent Document 2 detects the amount of change in the channel response, and performs correction based on the detected amount of change when computing metric data used for error correction from a demodulated signal.
Patent Document 1: Japanese Patent Publication No. 2006-311385
Patent Document 2: Japanese Patent Publication No. 2002-118533

### SUMMARY

Typically, a receiver for receiving an OFDM signal, such as one described in Patent Document 1, uses Viterbi decoding for error correction. While Viterbi decoding is suitable for correcting bit errors due to AWGN interference, Viterbi decoding is not fully effective in correcting bit errors due to multipath interference. Therefore, one problem is that performing Viterbi decoding on a received signal subjected to multipath interference may degrade the reception performance.

A receiver of Patent Document 2 detects the amount of change in the channel response based on a received signal, and corrects metric data using the detected amount of change. There are various factors in change in a channel response including, in addition to multipath interference, AWGN interference, fading interference which occurs during on-the-move reception, etc. Thus, even when a detected amount of change is the same as that in another case, the factors causing the both changes in channel responses may not necessarily be a same type of interference. One problem is that, if correction is performed on the metric data when the type of the interference experienced is different from the type of assumed interference, then the error correction cannot be fully effective, thereby also causing the reception performance to be degraded.

It is an object of the present invention to provide a receiver capable of proper demodulation and error correction in various transmission environments.

A receiver according to the embodiment of the present invention is a receiver for receiving a digitally modulated signal, including a demodulator configured to select one demodulation scheme from a plurality of predetermined demodulation schemes based on the received signal, and to demodulate the received signal using the selected demodulation scheme to generate a demodulated signal, and a demapper configured to obtain metric data by making a soft decision on the demodulated signal. The demapper converts the demodulated signal into the metric data according to the selected demodulation scheme.

According to this, the receiver converts the demodulated signal into the metric data according to the demodulation scheme selected in the demodulator; thus, effective error correction is also possible for signals transmitted through various transmission channels under different conditions.

A receiving method according to the embodiment of the present invention is a receiving method for receiving a digitally modulated signal, including steps of selecting one demodulation scheme from a plurality of predetermined demodulation schemes based on the received signal, and demodulating the received signal using the selected demodulation scheme to generate a demodulated signal, and obtaining metric data by making a soft decision on the demodulated signal, where when making the soft decision, the demodulated signal is converted into the metric data according to the selected demodulation scheme.

According to the embodiment of the present invention, the optimum demodulation scheme is selected from a plurality of demodulation schemes, and a demodulated signal is converted into metric data according to the selected demodulation scheme; therefore, effective error correction can be provided even if the conditions of transmission channels are different. Moreover, reception performance can be improved at low cost.

### BRIEF DESCRIPTION OF THE DRAWINGS

FIG. 1 is a block diagram illustrating a configuration of a receiver according to the example embodiment of the present invention.

FIG. 2 is a diagram for illustrating a part of the transmission format of the ISDB-T standard.

FIG. 3 is a block diagram illustrating an example configuration of the scheme determination section of FIG. 1.

FIG. 4 is a block diagram illustrating an example configuration of the demapper of FIG. 1.

FIG. 5 is a constellation diagram for a QPSK-modulated carrier.

FIG. 6A is a graph showing an example of the function used for conversion in the metric converter of FIG. 4. FIG. 6B is a graph showing another example of the function used for conversion in the metric converter of FIG. 4.

FIG. 7 is a block diagram illustrating a configuration of a variation of the demapper of FIG. 4.

### DETAILED DESCRIPTION

An example embodiment of the present invention will be described below with reference to the drawings.

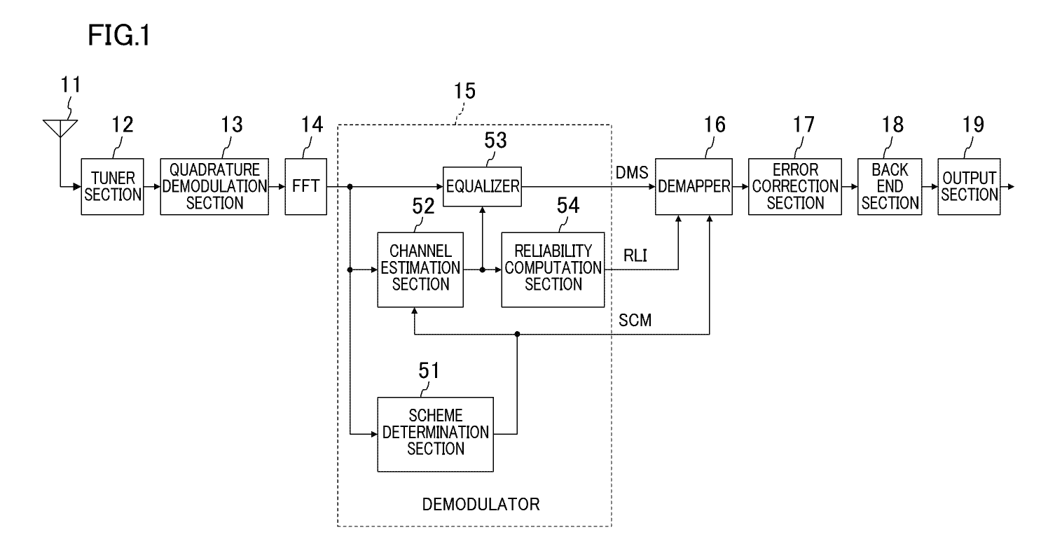

FIG. 1 is a block diagram illustrating a configuration of a receiver according to the example embodiment of the present invention. The receiver of FIG. 1 receives a signal (digitally modulated signal) obtained by digital modulation of carriers based on information to be transmitted, and transmitted through a transmission channel. Here, a case where the receiver of FIG. 1 receives a transmitted OFDM signal is described as an example. The receiver of FIG. 1 includes a tuner section 12, a quadrature demodulation section 13, an FFT section 14, a demodulator 15, a demapper 16, an error correction section 17, a back end section 18, and an output section 19.

An antenna 11 receives transmitted OFDM signals in the radio frequency (RF) band, and outputs the signals to the tuner section 12. The tuner section 12 selects an OFDM signal of a predetermined channel from the input OFDM signals in the RF band, obtains an OFDM signal in the intermediate frequency (IF) band by frequency conversion, and outputs the obtained signal to the quadrature demodulation section 13. The quadrature demodulation section 13 performs frequency conversion on the OFDM signal in the IF band into a baseband signal, generates a time-domain OFDM signal having in-phase (I) and quadrature (Q) components, and outputs the time-domain OFDM signal to the FFT section 14. The FFT section 14 performs an FFT on the time-domain OFDM signal, thereby generates a frequency-domain OFDM signal, and outputs the frequency-domain OFDM signal to the demodulator 15.

The demodulator 15 selects one demodulation scheme from a plurality of predetermined demodulation schemes based on the frequency-domain OFDM signal, and demodulates the frequency-domain OFDM signal using the selected demodulation scheme to generate a demodulated signal DMS. As used herein, the term “demodulation” includes at least equalization, and does not include demapping. Typically, the term “demodulation” includes processes during and before obtaining a constellation point of an equalized signal. The demodulator 15 performs compensation (equalization) for amplitude and phase distortion occurred in a transmission channel on the frequency-domain OFDM signal to generate the demodulated signal DMS, and outputs the demodulated signal DMS to the demapper 16. The demodulator 15 also outputs a scheme indication signal SCM, which indicates the demodulation scheme used for generating the demodulated signal DMS. Moreover, the demodulator 15 generates reliability information RLI, which represents the level of reliability of the demodulated signal DMS with respect to each carrier, and outputs the reliability information RLI to the demapper 16.

The demapper 16 obtains metric data by making a soft decision on the demodulated signal DMS input from the demodulator 15 based on both the reliability information RLI and the demodulation scheme indicated by the scheme indication signal SCM obtained from the demodulator 15. That is, the demapper 16 computes the metric data which represents “likelihood of being 0” and “likelihood of being 1” for each bit transmitted on each carrier, and outputs the metric data to the error correction section 17. The error correction section 17 performs various error correction processes, such as deinterleaving, Viterbi decoding, and/or Reed-Solomon decoding, and then outputs the correction result to the back end section 18 as a transport stream.

The back end section 18 performs, for example, separation of the transport stream input from the error correction section 17 into signals for respective sources such as video and audio, and decompression of data (e.g., MPEG decoding) to reproduce video, audio, and other digital data, and then outputs the reproduced video, audio, and other digital data to the output section 19. The output section 19 includes, for example, a display monitor for displaying the video, a speaker for outputting the audio, an external output terminal for outputting the digital data, etc.

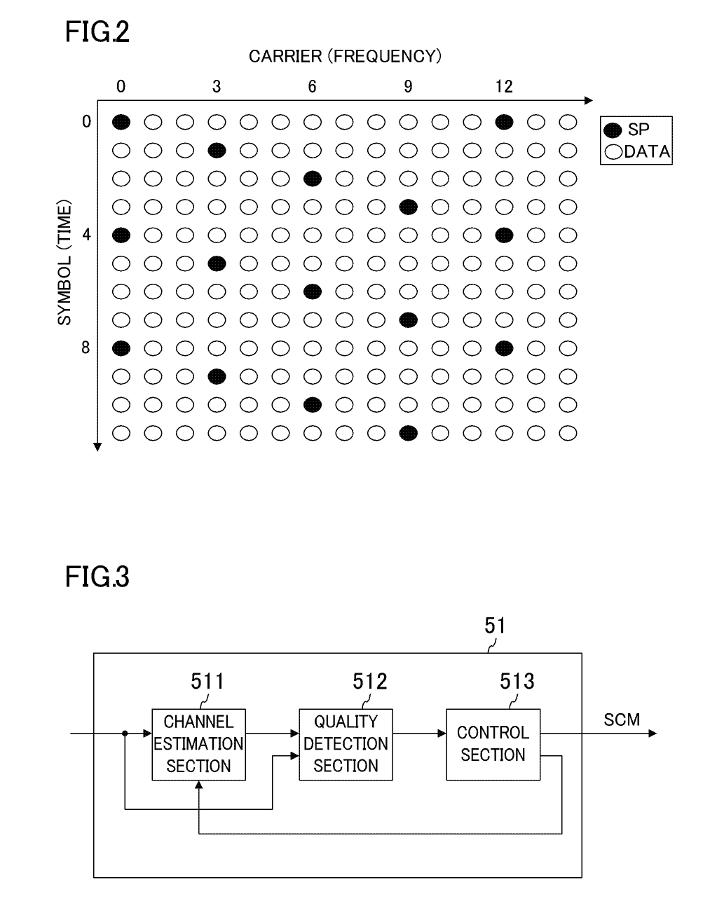

The OFDM signal received by the receiver of FIG. 1 is, for example, a signal in compliance with the integrated services digital broadcasting—terrestrial (ISDB-T) standard. FIG. 2 is a diagram for illustrating a part of the transmission format of the ISDB-T standard. In FIG. 2, the vertical axis is a time axis representing a symbol number; and the horizontal axis is a frequency axis representing a carrier number. An open circle represents a data signal for transmitting information such as video and audio. The data signal is modulated according to a modulation scheme such as 64 quadrature amplitude modulation (QAM) or quaternary phase shift keying (QPSK). A closed circle represents a pilot signal called scattered pilot (SP) signal.

The SP signals are inserted to estimate the transfer function of a transmission channel (i.e., channel response) in the receiver side, and the insert positions, amplitudes, and phases thereof are known in the receiver side. A channel response corresponds to distortion in an amplitude and/or a phase of a received signal due to multipath interference etc. occurred in the transmission channel. The SP signals have a same amplitude and a same phase for each carrier in which the SP signals are inserted. In addition, as shown in FIG. 2, the SP signals are inserted every predetermined time period; in the time-axis direction (or symbol-wise), the SP signals are inserted at a rate of one symbol every four symbols, and in the frequency-axis direction (or carrier-wise), the carriers are arranged such that a carrier in which SP signals are inserted appears every three carriers. The FFT section 14 in FIG. 1 obtains a frequency-domain OFDM signal including signals of respective carriers for each symbol, as shown in FIG. 2. Each of these signals is a complex signal having I and Q components.

The demodulator 15 in FIG. 1 includes a scheme determination section 51, a channel estimation section 52, an equalizer 53, and a reliability computation section 54. The frequency-domain OFDM signal obtained in the FFT section 14 is input to the scheme determination section 51, to the channel estimation section 52, and to the equalizer 53. The scheme determination section 51 selects one suitable estimation method for the channel conditions from a plurality of predetermined estimation methods for estimating the channel response of the transmission channel through which the received OFDM signal has passed, and outputs the scheme indication signal SCM which indicates the suitable demodulation scheme selected to both the channel estimation section 52 and the demapper 16.

Demodulation schemes which obtain and use channel responses by different estimation methods are considered to be different demodulation schemes. That is, a plurality of methods for estimating a channel response respectively correspond to a plurality of demodulation schemes. Thus, the scheme determination section 51 can be said to select one demodulation scheme from a plurality of predetermined demodulation schemes.

The channel estimation section 52 estimates, from the frequency-domain OFDM signal, the channel response of the transmission channel through which the received OFDM signal has passed based on the scheme indication signal SCM input from the scheme determination section 51. Specifically, the channel estimation section 52 first obtains the channel response corresponding to a received SP signal. Then, the channel estimation section 52 obtains channel responses corresponding to respective data signals by, for example, interpolating the channel response corresponding to the received SP signal both symbol-wise and carrier-wise based on the scheme indication signal SCM, and outputs the channel responses corresponding to respective data signals to both the equalizer 53 and the reliability computation section 54.

The equalizer 53 performs compensation (equalization) for amplitude and phase distortion occurred in the transmission channel on the frequency-domain OFDM signal using the channel response obtained from the channel estimation section 52 (in other words, using the demodulation scheme selected in the scheme determination section 51), and outputs the result to the demapper 16 as the demodulated signal DMS. The reliability computation section 54 computes the reliability information RUT, which represents the level of reliability of the demodulated signal DMS, for each carrier from the channel response obtained from the channel estimation section 52, and outputs the reliability information RLI to the demapper 16. For example, the reliability information RLI is computed based on the power (the sum of square of I component and square of Q component) of the channel response. In such a case, the obtained reliability information indicates that a carrier having a higher power of channel response has higher reliability, while a carrier having a lower power of channel response has lower reliability.

In general, examples of known methods for estimating the channel response of an OFDM signal include a method in which first the channel response corresponding to an SP signal is obtained, next interpolation is performed symbol-wise, then interpolation is performed carrier-wise; and a method in which no interpolation is performed symbol-wise, but interpolation is performed only carrier-wise for each symbol. The estimation accuracy of the channel response after interpolation varies depending on the interpolation method used. For example, performance during on-the-move reception is improved if the method is used in which no interpolation is performed symbol-wise, but interpolation is performed only carrier-wise for each symbol.

In addition, generally, such an interpolation process is often performed using a filter, and thus the estimation accuracy of the channel response after interpolation also depends on the coefficients of the filter. For example, a wider pass bandwidth of a filter for carrier-wise interpolation provides higher estimation accuracy of the channel response with respect to multipath interference having a long delay time. Meanwhile, a narrower pass bandwidth provides lower estimation accuracy with respect to multipath interference having a long delay time, but provides higher estimation accuracy with respect to AWGN interference.

Accordingly, the channel estimation section 52 selects and uses a method for interpolating the channel response and filter characteristic (filter coefficients) based on the scheme indication signal SCM, which indicates a suitable estimation method, input from the scheme determination section 51, and thus suitably estimates the channel response for each transmission channel affected differently by multipath interference, AWGN interference, etc. Since the equalization is performed based on the channel response thus obtained, the equalizer 53 performs suitable equalization based on the conditions of each transmission channel.

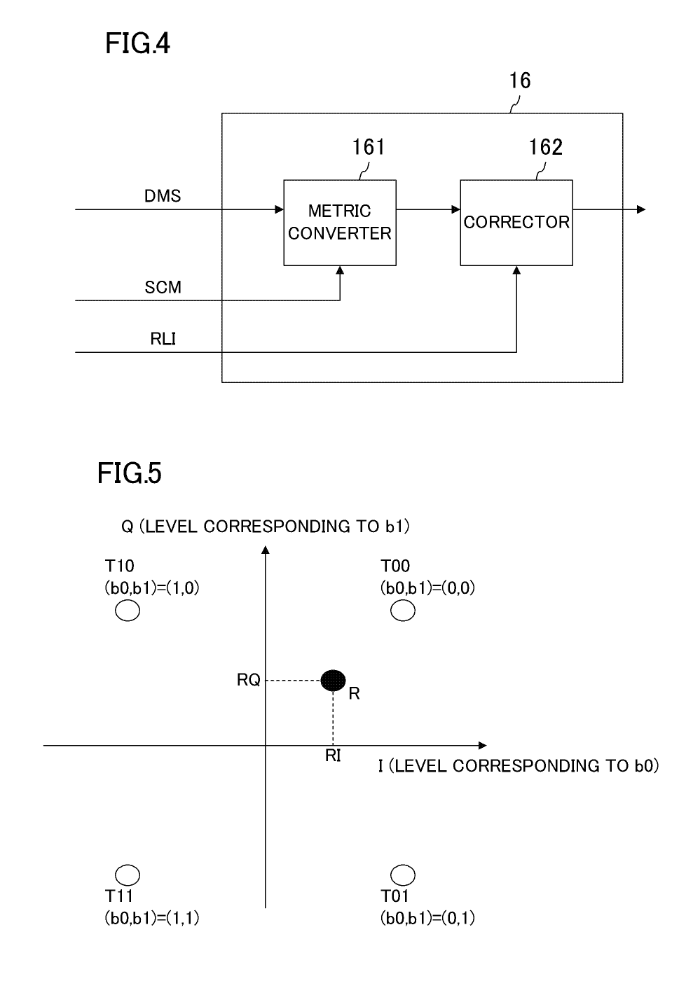

Next, the scheme determination section 51 will be described. FIG. 3 is a block diagram illustrating an example configuration of the scheme determination section 51 of FIG. 1. The scheme determination section 51 of FIG. 3 includes a channel estimation section 511, a quality detection section 512, and a control section 513. The frequency-domain OFDM signal output from the FFT section 14 is input to each of the channel estimation section 511, the quality detection section 512, and the control section 513.

Similarly to the channel estimation section 52 described above, the channel estimation section 511 estimates a channel response from a frequency-domain OFDM signal. A difference is that the channel estimation section 511 estimates the channel response based on the scheme indication signal input from the control section 513. That is, the channel estimation section 511 obtains the channel response corresponding to a data signal by interpolating the channel response corresponding to an SP signal both symbol-wise and carrier-wise based on the scheme indication signal input from the control section 513, and outputs the obtained channel response to the quality detection section 512.

The quality detection section 512 detects a quality value representing the quality of a received signal from both the frequency-domain OFDM signal and the channel response obtained in the channel estimation section 511, and outputs the quality value to the control section 513. For example, the quality detection section 512 equalizes the input frequency-domain OFDM signal using the channel response obtained in the channel estimation section 511, detects the difference between the equalized signal and an ideal signal, and assumes the difference to be the quality value. That is, the quality detection section 512 obtains the quality value from the distance between an ideal constellation point and the equalized constellation point on the I-Q plane.

The quality value varies depending on the channel response used for the computation. A smaller difference between a channel response indicating actual channel conditions and an estimated channel response (i.e., a higher estimation accuracy of a channel response) results in an equalized signal of higher quality. Accordingly, a higher estimation accuracy of a channel response in the channel estimation section 511 causes a quality value which represents higher quality in the quality detection section 512. Note that the method for detecting the quality value described herein is presented merely by way of example, and the quality value may be obtained by another method.

The control section 513 selects one method to be used to estimate a channel response in the channel estimation section 511 from a plurality of predetermined estimation methods for estimating the channel response, and outputs the result to the channel estimation section 511 as a scheme indication signal. Then, when the control section 513 receives, from the quality detection section 512, the quality value corresponding to the channel response obtained using the estimation method specified for the channel estimation section 511, the control section 513 selects another method to be used to estimate the channel response in the channel estimation section 511, and outputs the result to the channel estimation section 511 as a scheme indication signal.

As described above, the control section 513 obtains quality values corresponding to respective methods while sequentially switching the method used for estimating the channel response in the channel estimation section 511. In addition, the control section 513 compares the quality values obtained in this way corresponding to all respective estimation methods for estimating the channel response, and determines a single estimation method which provides the best quality value. Each of the components of the scheme determination section 51 repeats the operation described above. The control section 513 outputs the scheme indication signal SCM, which represents the method obtained by this determination operation, to the channel estimation section 52 and to the demapper 16. In this regard, it is preferred that the plurality of methods used for estimating the channel response in the channel estimation section 511 be provided in advance, which are, for example, methods with different interpolation methods, methods with different filter coefficients for use, etc., and that methods effective in improving the channel response respectively for AWGN interference and multipath interference be selected as candidate methods in advance.

For example, a plurality of types of filters corresponding to the plurality of methods used for estimating the channel response are provided in advance as filters used for carrier-wise interpolation. Here, it is assumed that one is a filter having a narrower pass bandwidth, and the other is a filter having a wider pass bandwidth. In such a case, for a transmission channel with no multipath interference or a transmission channel in which AWGN interference is predominant, a demodulated signal DMS which is obtained based on a channel response estimated using the filter having a narrower pass bandwidth has higher quality. Thus, a scheme indication signal corresponding to this filter, that is, a scheme indication signal indicating a method suitable for AWGN interference, is output. On the contrary, for a transmission channel with multipath interference, a demodulated signal DMS obtained by using the filter having a wider pass bandwidth has higher quality. Thus, a scheme indication signal corresponding to this filter, that is, a scheme indication signal indicating a method suitable for multipath interference, is output. As s result, the scheme determination section 51 determines a suitable demodulation scheme based on the conditions of a transmission channel affected by AWGN interference, multipath interference, etc., and outputs the result as the scheme indication signal.

FIG. 4 is a block diagram illustrating an example configuration of the demapper 16 of FIG. 1. As shown in FIG. 4, the demapper 16 includes a metric converter 161 and a corrector 162. The demodulated signal and the scheme indication signal, and the reliability information each obtained from the demodulator 15 are respectively input to the metric converter 161 and the corrector 162.

The metric converter 161 makes a soft decision on the demodulated signal DMS. That is, the metric converter 161 does not make a decision to determine whether a bit obtained from each demodulated carrier is “0” or “1” (so-called “hard decision”), but makes a decision to determine the degree of likelihood of being “0” or likelihood of being “1” using a value between “0” and “1” (so-called “soft decision”), and obtains metric data (also generally called “likelihood” etc.) as the determination result.

FIG. 5 is a constellation diagram for a QPSK-modulated carrier. FIG. 5 shows the location of a constellation point of the carrier on the I-Q plane. In QPSK modulation, a transmitter performs a process to assign a carrier every two bits of an information bit sequence (a process so-called “mapping”) to transmit the bit sequence. For example, in the transmission standard ISDB-T adopted for digital terrestrial broadcasting in Japan, the mapping is performed such that one of the constellation points T00, T10, T11, and T01 is selected based on the bit sequence (b0, b1) to be transmitted on each carrier. That is, the bit sequence is mapped onto:
T00 when (b0, b1)=(0, 0),
T01 when (b0, b1)=(0, 1),
T10 when (b0, b1)=(1, 0), or
T11 when (b0, b1)=(1, 1).

Unless a disturbance occurs on the transmission channel, the constellation point of the demodulated signal input to the demapper 16 should match one of the ideal constellation points T00, T01, T10, and T11; however, depending on a disturbance such as AWGN interference or multipath interference, a mismatch can occur between the locations of the constellation point of the demodulated signal and the ideal constellation points. Assume that the demodulated signal input to the demapper 16 is shown at a location of a point R on the I-Q plane, and that the I and the Q components thereof are respectively RI and RQ. The I and the Q components RI and RQ respectively correspond to the levels of bits b0 and b1 of the transmitted bit sequence.

The metric converter 161 converts the demodulated signal DMS into the metric data representing the likelihood of being “0” and the likelihood of being “1” of each transmitted bit, and outputs the conversion result to the corrector 162. Specifically, the metric converter 161 converts the location of the constellation point R (i.e., the values of the I and the Q components of the constellation point R), which the demodulated signal DMS represents, into the metric data.

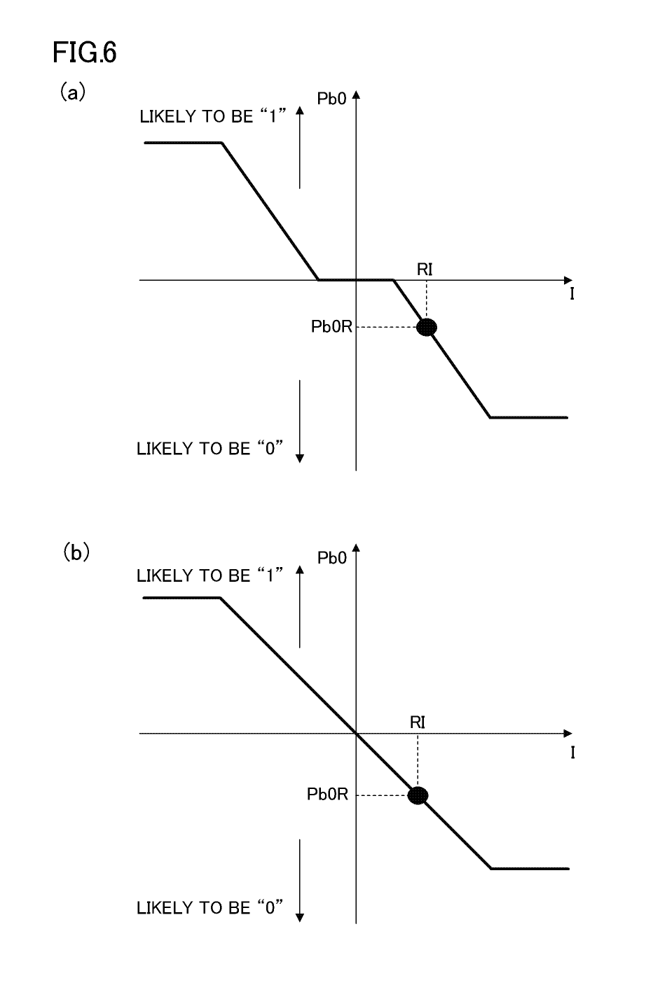

The relationship between the location of the constellation point R for the demodulated signal DMS and the metric values obtained by converting the location can also be defined as a function. FIG. 6A is a graph showing an example of the function used for conversion in the metric converter 161 of FIG. 4. FIG. 6B is a graph showing another example of the function used for conversion in the metric converter 161 of FIG. 4. The functions of FIGS. 6A and 6B both determine the metric data Pb0 for the bit b0 based on the I component RI of the constellation point R for the demodulated signal.

The metric converter 161 outputs as the metric data a value indicating that the transmitted bit b0 is more likely to be “0” when the value of the I component RI is large, while the transmitted bit b0 is more likely to be “1” when the value of the I component RI is small. Note that in FIG. 6A, the metric data Pb0 for the I component RI within a predetermined range including I=0 is constant at the average value of the maximum and the minimum of the metric data Pb0. In FIG. 6B, the metric data Pb0 continually changes depending on the value of the I component RI.

Although the foregoing description discusses a process to obtain the metric data Pb0 for the bit b0 from the I component RI of the constellation point R for the demodulated signal, the metric converter 161 obtains metric data for the bit b1 from the Q component RQ of the constellation point R in a similar way. The metric converter 161 switches the function used for conversion based on the value of the input scheme indication signal SCM, that is, based on the selected estimation method for estimating the channel response, when converting the input demodulated signal into the metric data. The corrector 162 corrects the metric data for the bits transmitted by each carrier based on the input reliability information RLI for the carrier, and outputs the corrected metric data to the error correction section 17.

An operation of the demapper 16 configured as described above will now be described. In an environment with multipath interference, the received power varies significantly depending on the location (frequency) of the carrier, and thus there may be a carrier having significantly smaller amount of power than the other carriers. Such a carrier has low reliability; therefore if the bits (metric data) transmitted by this carrier are used without change, this metric data contributes to a reduction in the overall effect of error correction. Thus, the corrector 162 corrects the values of the metric data obtained from carriers which are considered to have low reliability based on the reliability information, among the metric data after soft decisions, so that the values of the metric data approach a value indicating that the levels of likelihood of being “0” and likelihood of being “1” are the same (e.g., a value of Pb0 at the intersection point of the vertical and the horizontal axes in FIG. 6A).

Here, if when making a soft decision, a function as shown in FIG. 6A is used which outputs the metric data Pb0 having a value indicating that the levels of likelihood of being “1” and likelihood of being “0” are the same when the value on the horizontal axis is within a predetermined range, then the ratio of metric data indicating neither “0” nor “1” excessively increases. Therefore, an error correction using such metric data is not sufficiently effective in correction. Accordingly, for example, when the input scheme indication signal SCM indicates a scheme suitable for multipath interference, the metric converter 161 selects a function having a characteristic as shown in FIG. 6B, while otherwise (i.e., when the scheme indication signal SCM indicates that no multipath interference has occurred, or indicates a scheme suitable for AWGN interference), the metric converter 161 selects a function having a characteristic as shown in FIG. 6A.

As a result, even when metric data is corrected based on the reliability information for an environment with multipath interference, the ratio of metric data indicating neither “0” nor “1” is appropriately reduced. Thus, effective error correction can be provided, thereby allowing the reception performance to be improved as compared to when the characteristic of the metric conversion in a demapper is fixed.

Note that the function for use in the metric converter 161 may be determined in such a way that a plurality of functions respectively having different rates of change in the value of the metric data Pb0 to change in the value of the I component RI are preset, or a plurality of functions respectively having different upper or lower limits of the value of the metric data are preset, and then the metric converter 161 selects a function having a suitable characteristic based on the scheme selected in the demodulator 15 and indicated by the scheme indication signal SCM.

Although the foregoing description discusses an operation for the I component RI of the constellation point R for the demodulated signal, the demapper 16 performs a similar operation also for the Q component RQ of the constellation point R for the demodulated signal.

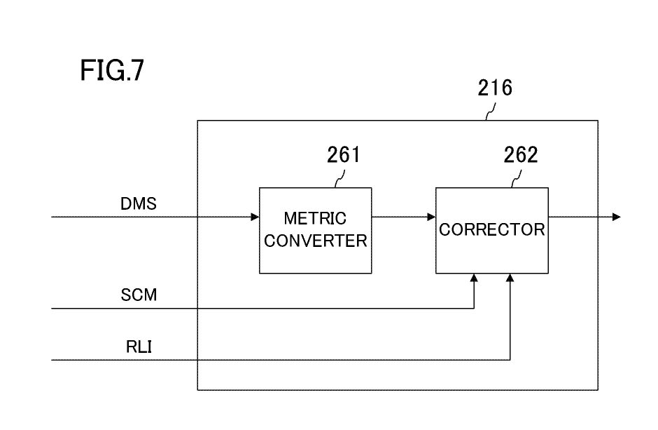

FIG. 7 is a block diagram illustrating a configuration of a variation of the demapper 16 of FIG. 4. The demapper 16 of FIG. 4 may be replaced with the demapper 216 of FIG. 7. The demapper 216 of FIG. 7 includes a metric converter 261 and a corrector 262. Except that the scheme indication signal SCM is not used, the metric converter 261 makes a soft decision on the demodulated signal DMS, and converts the demodulated signal DMS to metric data, similarly to the metric converter 161. The corrector 262 corrects the metric data not only based on the reliability information RLI similarly to the corrector 162, but also based on the scheme indication signal SCM.

The corrector 262 corrects the metric data obtained from carriers which are considered to have low reliability based on the reliability information RLI so that the values of the metric data approach a value indicating that the levels of likelihood of being “0” and likelihood of being “1” are the same, and moreover, if the scheme indication signal SCM indicates a scheme suitable for multipath interference, then the amount of correction is reduced. As a result, even when metric data is corrected based on the reliability information RLI in an environment with multipath interference, the ratio of metric data indicating neither “0” nor “1” is reduced, thereby allowing a more effective error correction to be provided.

Although the metric converter 161 etc. have been described as converting the demodulated signal DMS into the metric data using a function, a table etc. defining a relationship between the I component RI and the metric data may be used instead of the function. The operation of the metric converter 161 etc. may be performed in a computation unit etc. Device cost is not high in either case.

Although this embodiment has been described in which the reliability computation section 54 computes the reliability information RLI based on the power of a channel response, the computing method of the reliability information is not limited thereto. Any reliability information may be used as long as the reliability of the carrier can be evaluated based on the magnitude of the effect of interference occurred in a particular carrier (frequency).

Although this embodiment has been described in which the scheme determination section 51 of the demodulator 15 sequentially performs demodulation according to a plurality of demodulation schemes, and determines the optimum demodulation scheme, the scheme determination section 51 may, instead, perform demodulation according to a plurality of demodulation schemes in parallel, detect a plurality of quality values from demodulation results corresponding to the respective demodulation schemes, and determine the demodulation scheme producing the highest quality value. In this case also, the conversion process in the demapper 16 can be switched based on the selected demodulation scheme.

Although this embodiment has been described in terms of an OFDM signal according to the ISDB-T standard as an example of a received signal, the received signal may be one in compliance with a broadcast standard such as digital video broadcasting—terrestrial (DVB-T) or DVB-T2, or a transmission standard for wireless local area networks (LANs) etc., or may be other than an OFDM signal.

This embodiment can also be implemented on a receiver even if the receiver is one for receiving a signal in compliance with another transmission standard, or a single carrier modulated signals such as QAM-modulated signals or vestigial sideband (VSB)-modulated signals. In such a case, if the filter characteristic used for equalization of a received signal is designed so as to be adaptively changed depending on the channel response, then it is preferable that the characteristic at a time of making a soft decision on a demodulated signal and converting the demodulated signal into metric data be controlled so as to be switched based on the filter characteristic.

Thus, the receiver of this embodiment includes a demodulator which determines the optimum modulation scheme among a plurality of predetermined demodulation schemes, and which generates a demodulated signal based on the determined modulation scheme, and a demapper which converts the demodulated signal into metric data according to the modulation scheme selected in the demodulator. The receiver of this embodiment provides, in a simple configuration, effective error correction for a signal which has passed through a transmission channel with various interference including AWGN interference and multipath interference. Therefore, reception performance can be improved at low cost.

As described above, according to the example embodiment of the present invention, proper demodulation and error correction can be performed in various transmission environments, and therefore, the present invention is useful for receivers etc.

The many features and advantages of the invention are apparent from the detailed specification and, thus, it is intended by the appended claims to cover all such features and advantages of the invention which fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A receiver for receiving a digitally modulated signal, comprising:
a demodulator configured to select one demodulation scheme from a plurality of predetermined demodulation schemes based on the received signal, and to demodulate the received signal using the selected demodulation scheme to generate a demodulated signal; and
a demapper configured to obtain metric data by making a soft decision on the demodulated signal,
wherein
the demapper converts the demodulated signal into the metric data according to the selected demodulation scheme.

2. The receiver of claim 1, wherein
the demodulator includes
a scheme determination section configured to select, based on the received signal, one estimation method as the demodulation scheme from a plurality of predetermined estimation methods for estimating a channel response of a transmission channel through which the received signal has passed,
a channel estimation section configured to estimate the channel response of the transmission channel through which the received signal has passed using the estimation method selected in the scheme determination section, and
an equalizer configured to equalize the received signal using the estimated channel response, and to output an equalization result as the demodulated signal.

3. The receiver of claim 2, wherein
the scheme determination section sequentially obtains channel responses respectively corresponding to the plurality of predetermined estimation methods, and selects a best estimation method from the plurality of predetermined estimation methods based on the channel responses sequentially obtained.

4. The receiver of claim 2, wherein
the demodulator further includes a reliability computation section configured to compute reliability information of the demodulated signal from the estimated channel response, and
the demapper corrects the metric data based on the reliability information.

5. The receiver of claim 1, wherein
the demapper converts the demodulated signal into the metric data using a function based on the selected demodulation scheme.

6. The receiver of claim 1, wherein
the demapper corrects the metric data according to the selected demodulation scheme.

7. A receiving method for receiving a digitally modulated signal, comprising:
selecting one demodulation scheme from a plurality of predetermined demodulation schemes based on the received signal, and demodulating the received signal using the selected demodulation scheme to generate a demodulated signal; and
obtaining metric data by making a soft decision on the demodulated signal,
wherein
when making the soft decision, the demodulated signal is converted into the metric data according to the selected demodulation scheme.
